(19) United States
(12) Patent Application Publication
(10) Pub. No.: US 2025/0049122 A1
(43) Pub. Date: Feb. 13, 2025

(54) Heating Chamber Assembly for an Aerosol Generation Device

(71) Applicant: JT International SA, Geneva (CH)

(72) Inventor: Alec Wright, GUildford (GB)

(73) Assignee: JT International SA, Geneva (CH)

(21) Appl. No.: 18/717,828

(22) PCT Filed: Dec. 14, 2022
(86) PCT No.: PCT/EP2022/085975

§ 371 Date: Jun. 7, 2024

(30) Foreign Application Priority Data
Dec. 15, 2021 (EP) 21214914.0

(51) Int. Cl. A24F 40/46; A24F 40/20; A24F 40/70; H05B 3/14

(52) U.S. Cl. CPC A24F 40/46; A24F 40/20; A24F 40/70; H05B 3/141; H05B 2203/013

(57) ABSTRACT

A heating chamber assembly for an aerosol generation device includes a heating chamber configured to receive an aerosol generation substrate; and a tape casted resistive heating layer on an outer surface of the heating chamber, the tape casted resistive heating layer being configured to deliver heat to the heating chamber.

The present invention relates to a heating assembly for an aerosol generating device. The disclosure is particularly applicable to a portable aerosol generation device, which may be self-contained and low temperature. Such devices may heat, rather than burn, tobacco or other suitable aerosol substrate materials by conduction, convection, and/or radiation, to generate an aerosol for inhalation.

### BACKGROUND TO THE INVENTION

The popularity and use of reduced-risk or modified-risk devices (also known as vaporisers) has grown rapidly in the past few years as an aid to assist habitual smokers wishing to quit using traditional tobacco products such as cigarettes, cigars, cigarillos, and rolling tobacco. Various devices and systems are available that heat or warm aerosolisable substances as opposed to burning tobacco in conventional tobacco products.

A commonly available reduced-risk or modified-risk device is the heated substrate aerosol generation device or heat-not-burn (HNB) device. Devices of this type generate an aerosol or vapour by heating an aerosol substrate (i.e. consumable) that typically comprises moist leaf tobacco or other suitable aerosolisable material to a temperature typically in the range of 150° C. to 300° C. Heating an aerosol substrate, but not combusting or burning it, releases an aerosol that comprises the components sought by the user but not the undesirable by-products of combustion. In addition, the aerosol produced by heating the tobacco or other aerosolisable material does not typically comprise the burnt or bitter taste that may result from combustion that can be unpleasant for the user.

Thin film heaters have previously been used in aerosol generation devices, with the thin film heater being wrapped around a heating chamber, which is typically made of metal. The operation of the thin film heater then serves to heat the heating chamber and the aerosol generation substrate within. These thin film heaters have allowed for aerosol generation substrates to be heated in a more efficient manner, but there nevertheless remains a desire to provide an improved heater chamber assembly for use in aerosol generation devices and to enable the use of different materials when forming the heating chamber.

### SUMMARY OF THE INVENTION

According to a first aspect of the invention, a heating chamber assembly for an aerosol generation device is provided, the heating chamber assembly comprising: a heating chamber configured to receive an aerosol generation substrate, and a tape casted resistive heating layer on an outer surface of the heating chamber, the tape casted resistive heating layer being configured to deliver heat to the heating chamber.

When describing the configuration of the layers and elements comprising the heating chamber assembly, the word “on” should not be construed as limiting two elements to being in direct contact. For example, one or more intermediate layers may be provided between the tape casted resistive heating layer and the outer surface of the heating chamber.

The present invention also allows for the use of a wider range of materials for the other elements of the heating chamber assembly. This allows for more flexibility in how the heating chamber assembly is manufactured, as well as allowing for further advantages as discussed below. In particular, tape casting allows for the resistive heating layer to be formed in a separate step when manufacturing a heating chamber assembly. It can then be wrapped around an outer surface of the heating chamber in a conventional manner, increasing throughput when manufacturing heating chamber assemblies.

In advantageous embodiments of the invention, the tape casted resistive heating layer comprises one or more semiconductors, the one or more semiconductors preferably comprising one or more ceramic semiconductors, such as sintered silicon carbide, liquid phase sintered silicon carbide, and silicon infiltrated silicon carbide.

Compared to conventional heaters, ceramic semiconductors can be heated to a higher temperature, with ceramic semiconductors typically suitable for heating to 900° C. Conventional heaters, in contrast, are made from materials with meting points of around 280° C. Although in most embodiments the aerosol generation substrates would not be heated to beyond 320° C., this is above the melting point of most conventional heaters and ceramic semiconductors therefore allow for aerosol generation substrates to be heated to higher temperatures. In addition to allowing for aerosol generation substrates to be heated to higher temperatures, the use of ceramic semiconductors allows for the heating chamber to be formed from materials having a lower thermal conductivity. For example, materials such as glass can be used to form the heating chamber.

In addition to the tape casted resistive heating layer, the heating chamber assembly may comprise a thermally sprayed resistive heating layer on an outer surface of the heating chamber, the thermally sprayed resistive heating layer being configured to deliver heat to the heating chamber. The tape casted resistive heating layer could be provided on the thermally sprayed resistive heating layer or between the thermally sprayed resistive heating layer and the outer surface of the heating chamber.

The thermally sprayed resistive heating layer may be configured in the same way as the tape casted resistive heating layer. Therefore, all features, configurations, and options described with relation to a tape casted resistive heating layer may be implemented in a thermally sprayed resistive heating layer, and vice versa.

Thermally sprayed resistive heating layers are advantageously found to exhibit a high degree of conformity to the outer surface of the heating chamber (or an intermediate layer on which the thermally sprayed resistive layer is provided), thereby improving the efficiency of the transfer of heat from the resistive heating layer to the heating chamber and, therefore, to an aerosol generation substrate received in the heating chamber. This in turn enables the use of a wider range of materials for the heating chamber, whereas conventionally it is necessary to form heating chambers from materials having a high thermal conductivity such as metal.

This arrangement is particularly advantageous when different materials are to be used to provide resistive heating layers, as some materials are especially suited to tape casting and others to thermal spraying. For example, silicon infiltrated silicon carbide is well suited to tape casting.

Other configurations of resistive heating layer are also possible, with the thermally sprayed resistive heating layer and/or tape casted resistive heating layer comprising one or more electrical insulators. For example, a resistive heating layer may comprise two or more different materials formed in a pattern with the two or more different materials separated by insulating material.

Although, as noted above, an advantage of the present invention is that it is not necessary to use a thermally conductive material to form the heating chamber, it may nevertheless be desirable to use a thermally conductive material. Such materials, such as metal, are often also electrically conductive and the heating chamber assembly may, therefore, further comprise an electrical insulation layer between the tape casted resistive heating layer and the heating chamber. For example, the electrical insulation layer may comprise a functionalized silica coating, with organosilica coatings such as SiOₓ:CH_{y}, also known as Dursan™, being especially advantageous.

According to a second aspect of the invention, a method of manufacturing a heating chamber assembly for an aerosol generation device, the method comprising: providing a heating chamber configured to receive an aerosol generation substrate; tape casting a resistive heating layer, the resistive heating layer being configured to deliver heat to the heating chamber; and wrapping the taped casted resistive heating layer around an outer surface of the heating chamber.

The expression “wrapping around” should be interpreted in the same sense as the word “on” defined above, in the sense that one or more intermediate layers may be positioned between the tape casted resistive heating layer and the outer surface of the heating chamber. For example, one or more thermally sprayed resistive heating layers and/or one or more electrical insulation layers could be provided between the tape casted resistive heating layer and the outer surface of the heating chamber.

As discussed above in relation to the first aspect of the invention, the use of tape casting is advantageous as it allows a resistive heating layer to be produced in a distinct step from the other steps of the method and subsequently wrapped around an outer surface of the heating chamber.

Tape casting is also particularly advantageous when different materials are to be used to provide resistive heating layers, as some materials are especially suited to tape casting and others to thermal spraying, with silicon infiltrated silicon carbide being especially well suited to tape casting.

In addition, the method may comprise thermally spraying a resistive heating layer on an outer surface of the heating chamber. As discussed above in relation to the first aspect of the invention, thermally spraying the resistive heating layer leads to a high degree of conformity between the thermally sprayed resistive heating layer and the outer surface of the heating chamber (or an intermediate layer on which the thermally sprayed resistive layer is provided), thereby improving the efficiency of the transfer of heat from the resistive heating layer to the heating chamber and, therefore, to an aerosol generation substrate received in the heating chamber.

Among the available methods for thermally spraying the resistive heating layer, atmospheric plasma spraying and high velocity oxygen fuel spraying have been found to lead to an especially high degree of conformity between the thermally sprayed resistive heating layer and the outer surface of the heating chamber (or any intermediate layers).

The method may further comprise providing an electrical insulation layer between the resistive heating layer and the heating chamber. For example, the electrical insulation layer may comprise a functionalized silica coating, with organosilica coatings such as SiOₓ:CH_{y}, also known as Dursan™, being especially advantageous. As discussed above in relation to the first aspect of the invention, providing an electrical insulation layer allows for the use of electrically conductive material for the heating chamber, which may be advantageous in some cases.

Providing an electrical insulation layer between the resistive heating layer and the heating chamber preferably comprises applying the electrical insulation layer by chemical vapour deposition. Chemical vapour deposition of the electrical insulation layer leads to a high degree of conformity between the electrical insulation layer and the outer surface of the heating chamber (or an intermediate layer on which the electrical insulation layer is provided). This improves the efficiency of the transfer of heat across the electrical insulation layer and, therefore, to an aerosol generation substrate received in the heating chamber.

### BRIEF DESCRIPTION OF THE DRAWINGS

Embodiments of the invention are now described, by way of example, with reference to the drawings, in which:

FIG. 1 shows an exemplary aerosol generating device according to an embodiment of the invention;

FIG. 2 is a schematic cross-sectional view of a heating chamber assembly comprising a resistive heating layer;

FIG. 3 is a schematic cross-sectional view of a heating chamber assembly comprising a resistive heating layer and an electrical insulation layer;

FIG. 4 is a schematic cross-sectional view of another heating chamber assembly comprising a resistive heating layer and an electrical insulation layer; and

FIG. 5 is a flow diagram showing steps for manufacturing a heating chamber assembly according to an embodiment of the invention.

### DETAILED DESCRIPTION OF THE INVENTION

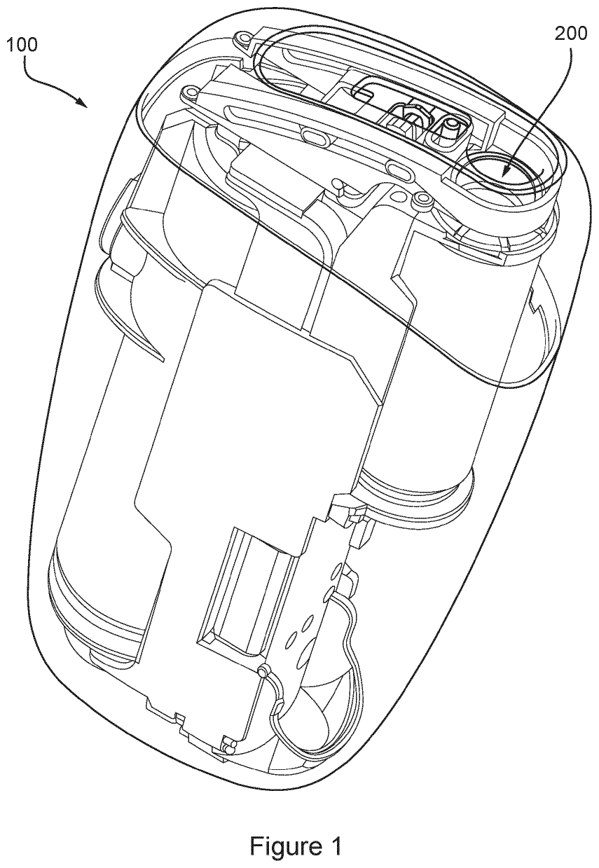

FIG. 1 illustrates an aerosol generation device 100 according to an embodiment of the invention. The aerosol generation device 100 is illustrated in an assembled configuration with the internal components visible. The aerosol generation device 100 is a heat-not-burn device, which may also be referred to as a tobacco-vapour device, and comprises a heating chamber assembly 200 configured to receive an aerosol substrate such as a rod of aerosol generating material, e.g. tobacco. The heating chamber assembly 200 is operable to heat, but not burn, the rod of aerosol generating material to produce a vapour or aerosol for inhalation by a user. Of course, the skilled person will appreciate that the aerosol generation device 100 depicted in FIG. 1 is simply an exemplary aerosol generation device according to the invention. Other types and configurations of tobacco vapour products, vaporisers, or electronic cigarettes may also be provided according to the invention.

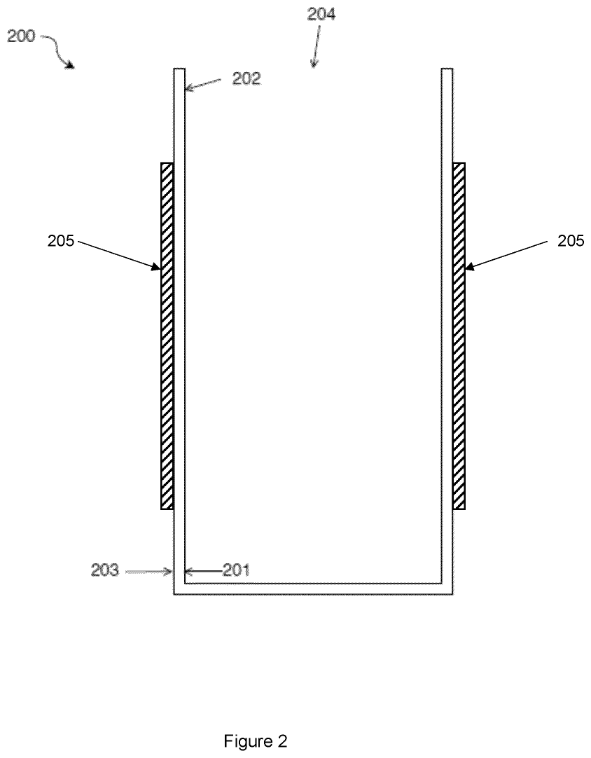

FIG. 2 shows a cross-sectional schematic view of the heating chamber assembly 200 according to an embodiment of the invention. The heating chamber assembly 200 comprises a heating chamber 202, which may be referred to as a thermally conductive shell, configured to receive an aerosol generation substrate, which may be referred to as a consumable. In particular, the heating chamber 202 is configured to receive an aerosol generation substrate having the form of a rod. To this end, the heating chamber 202 is preferably tubular, i.e. elongate and substantially cylindrical (having either a substantially circular or substantially oval cross section), with an opening 204 being positioned at a longitudinal end of the heating chamber 202. A user may insert an aerosol generation substrate through the opening 204 in the heating chamber 202 such that the aerosol generation substrate is positioned within the heating chamber 202 and interfaces with an inner surface 201 of the heating chamber 202. The length of the heating chamber 202 may be configured such that a portion of the aerosol generation substrate protrudes through the opening 204 in the heating chamber 202. Returning to FIG. 1, said portion of the aerosol generation substrate will then protrude out of the heating chamber assembly 200, allowing it to be received in the mouth of the user.

The skilled person will appreciate that the heating chamber 202 is not limited to being cylindrical. For example, the heating chamber 202 may be formed as a cuboidal, conical, hemi-spherical or other shaped cavity, and be configured to receive a complementary shaped aerosol substrate. Moreover, in some embodiments, the heating chamber 202 may not entirely surround the aerosol substrate, but instead only contact a limited area of the aerosol substrate.

For example, the heating chamber 202 may be substantially cylindrical but comprise one or more elongate recessed regions that protrude inwardly to form elongate protrusions on the inner surface 201 of the heating chamber 202. In another example, the heating chamber 202 may be substantially cylindrical but comprise one or more flattened regions that extend in an axial direction of the heating chamber 202.

A resistive heating layer 205 surrounds an outer surface 203 of the heating chamber 202. In particular, the resistive heating layer 205 lies adjacent to (i.e. abuts, contacts) the circumferential outer surface 203 of the heating chamber 202. The resistive heating layer 205 is directly bonded to the outer surface 203 of the heating chamber 202, i.e. chemical bonds are formed between the resistive heating layer 205 and the heating chamber 202. In FIG. 2, the resistive heating layer 205 is depicted as only extending along a portion of the length of the outer surface 203 of the heating chamber 202. However, the skilled person will appreciate that, in other embodiments, the resistive heating layer 205 may extend along the entire length of the heating chamber 202. Moreover, the skilled person will appreciate that the resistive heating layer 205 may only partially surround the outer surface of the heating chamber 202, which is to say that there may be gaps in the resistive heating layer 205 in the circumferential direction around the heating chamber 202.

The resistive heating layer 205 is configured to operate as a Joule heater. In other words, the resistive heating layer 205 is configured to release heat in response the flow of electrical current. Although this physical effect is primarily referred to herein as resistive heating, it may also be referred to as Joule heating or Ohmic heating. In use, power may be supplied to the resistive heating layer 205 from a power source such as a battery (not depicted) such that the temperature of the resistive heating layer 205 increases and heat energy is transferred to the heating chamber 202. The aerosol substrate received within the heating chamber 202 is conductively heated by the heating chamber 202 to produce an aerosol for inhalation by the user.

The resistive heating layer 205 is advantageously formed from one or more ceramic semiconductor materials, as these materials are suitable for heating to high temperatures (considered to be temperatures of 800 to 1000° C.). These ceramic semiconductor materials can be applied directly to the cup to form part of a heater assembly in the form of a coating by thermal spraying techniques such as atmospheric plasma spraying and high velocity oxygen fuel spraying, typically in a single layer, although multiple layers may also be used to form the resistive heating layer 205.

In some embodiments, the resistive heating layer 205 further comprises one or more ceramic semiconductor materials which have been tape casted and wrapped around the outer surface 203 of the heating chamber 202.

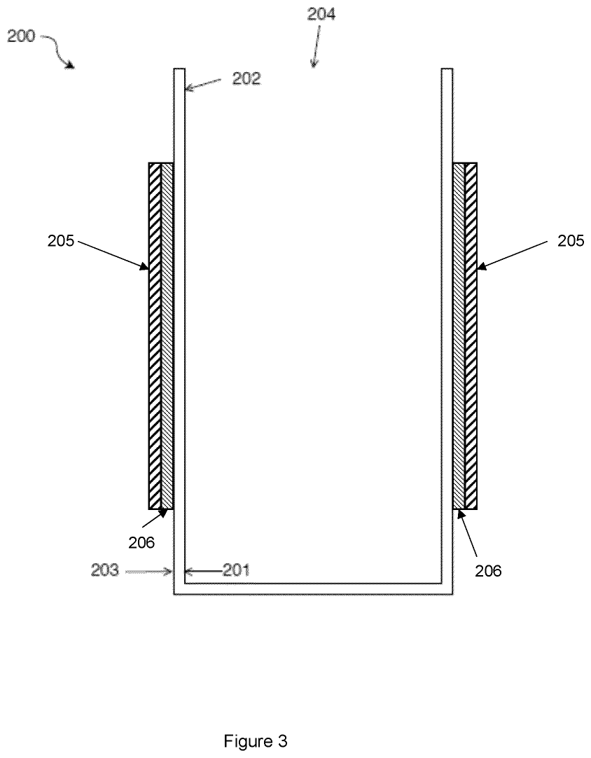

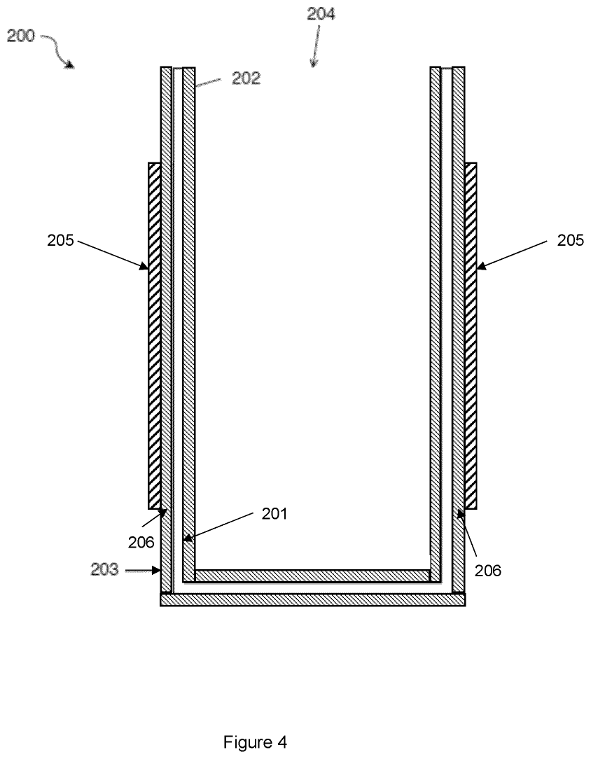

The resistive heating layer 205 may also comprise nonconductive materials provided in one or more coatings. These insulation layers may be provided between the resistive heating layer 205 and the outer surface 203 of the heating chamber 202, as is described in more detail below with reference to FIGS. 3 and 4, or they may be provided between two or more layers of ceramic semiconductor materials. They may also be provided in the same layer as one or more ceramic semiconductor materials.

For example, the one or more ceramic semiconductor materials may be thermally sprayed along with one or more nonconductive materials to create different heater geometries or different heating patterns, or to provide insulation layers.

Appropriate ceramic semiconductor materials include S-SiC (sintered silicon carbide), LPS-SiC (liquid phase sintered silicon carbide), and Si-SiC (silicon infiltrated silicon carbide). Si-SiC is particularly suitable for tape casting.

As the outer surface 203 of the heating chamber 202 and the resistive heating layer 205 form direct bonds with one another (i.e. they are chemically bonded at their interfaces) no air gaps or other thermal breaks exist between the components. Advantageously, this limits the thermal losses during operation and significantly improves the energy efficiency of the heating chamber assembly 200.

The skilled person will appreciate that the heating chamber 202 is not intended to act as a resistive heater and, therefore, should not receive a current. To this end, the heating chamber 202 is preferably formed from an electrically non-conductive material such as glass, removing the need to include a further insulation layer.

Nevertheless, it may be advantageous in some cases to form the heating chamber 202 out of an electrically conductive material such as metal, examples of which include steel or stainless steel or aluminium, in order to improve thermal conduction to an aerosol generation substrate. In such cases, an electrically insulating layer 206 is advantageously provided as these materials are often electrically conductive.

Two such embodiments are shown in FIGS. 3 and 4, in which electrical insulation layer 206 is provided between resistive heating layer 205 and the outer surface 203 of heating chamber 202. In this way, the coating of electrically insulating material 206 advantageously prevents a short circuit occurring between the heating element 208 and the heating chamber 202 by preventing contact between the coating of electrically conductive material 208 and the heating chamber 202, whilst allowing an efficient transfer of heat from the coating of electrically conductive material 208 to the heating chamber 202. That is, the coating of electrically insulating material 206 separates the coating of electrically conductive material 208 and the heating chamber 202 and ensures that a current does not flow from the coating of electrically conductive material 208 to the heating chamber 202.

The electrical insulation layer 206 is depicted as only extending along a portion of the length of the outer surface 203 of the heating chamber 202. However, the skilled person will appreciate that, similarly to the arrangement of the resistive heating layer 205, in other embodiments the electrical insulation layer 206 may extend along the entire length of the heating chamber 202, or even on the inner surface 201 of the heating chamber 202 as shown in FIG. 4. This latter option is particularly advantageous as it simplifies manufacture of the heating chamber assembly 200. When depositing an electrical insulation layer 206 on the heating chamber 202, for example in a chemical vapour deposition process, it is necessary to provide a masking layer in those regions of the surface of the heating chamber 202 in which the electrical insulation layer 206 is absent in the final heating chamber assembly 200. This masking layer is then removed, to leave an electrical insulation layer 206 in those regions where the masking layer was not present. By providing the electrical insulation layer 206 across the entire surface of the heating chamber 202, it is not necessary to provide a masking layer during deposition of the electrical insulation layer 206, thereby simplifying manufacture of the heating chamber assembly 200. The electrical insulation layer 206 also serves to prevent oxidization of the inner 201 and outer 203 surfaces of heating chamber 202. Nevertheless, the skilled person will appreciate that the coating of electrically insulating material 206 may only partially surround the outer surface of the heating chamber 202, which is to say that there may be gaps in the electrical insulation layer 206 in the circumferential direction around the heating chamber 202. However, the resistive heating layer 205 will typically not extend beyond the electrical insulation layer in either the longitudinal or circumferential direction.

As the outer surface 203 of the heating chamber 202, the electrical insulation layer 206, and the thermally sprayed resistive heating layer 205 form direct bonds with one another (i.e. they are chemically bonded at their interfaces) no air gaps or other thermal breaks exist between the components. Advantageously, this limits the thermal losses during operation and significantly improves the energy efficiency of the heating assembly 200.

In the embodiments illustrated in FIGS. 3 and 4, the resistive heating layer 205 is formed as a continuous surface that entirely surrounds the electrical insulation layer 206 in a circumferential direction of the heating chamber. That is, the resistive heating layer 205 covers the electrical insulation layer 206 such that no portion of the electrical insulation layer 206, at least in the circumferential direction, is exposed. However, as noted above, the resistive heating layer heating layer 205 may be patterned, in which case the restive heating layer will only partially cover the electrical insulation layer 206.

The electrical insulation layer 206 preferably comprises a material exhibiting a high electrical breakdown voltage (e.g. at about 100 Volt or higher) and high thermal conductivity. For example, the electrical insulation layer 206 may comprise ceramic, silicone, glass, silicone oxide, carbon or a combination thereof. In another example, the coating of electrically insulating material 206 may comprise (or optionally consist of) diamond-like-carbon (DLC). Other preferable materials include functionalized silicas such as organosilicas such as SiO_{X}:CH_{y}, also known as Dursan™. Preferably, the electrical insulation layer 206 has a thickness of between 0.1 to 10 micron, more preferably between 0.2 and 3 micron. Such properties provide improved heat transfer to the aerosol generation substrate received within the heating chamber 202, whilst ensuring that the heating chamber 202 remains electrically insulated. Advantageously, the heat-up time and cool-down time of the heating chamber 202 may be reduced, thereby improving the energy efficiency of the heating assembly 200.

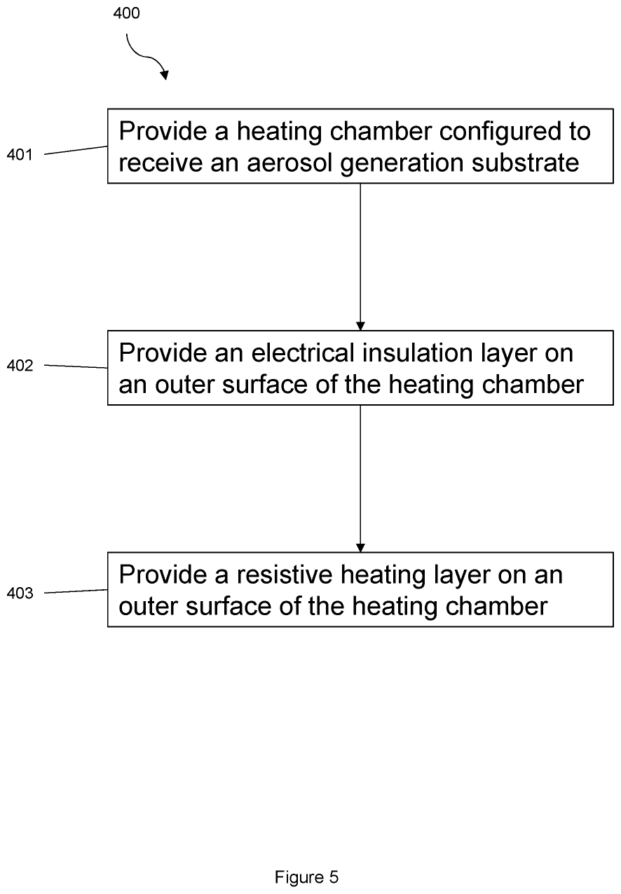

A method of manufacturing a heating chamber assembly according to an embodiment of the invention, for example a heating chamber assembly as shown in FIG. 2, 3, or 4, is depicted in FIG. 5.

The method 400 beings in step 401, in which a heating chamber configured to receive an aerosol generation device is provided. This heating chamber may be provided according to any known methods, either in a separate stage prior to method 400 or in an earlier step prior to step 401 as part of method 400.

An optional step 402 of providing an electrical insulation layer on an outer surface of the heating chamber may occur after step 401, either directly on an outer surface of the heating chamber or on an intermediate layer, although in some embodiments this step will be omitted. For example, when producing a heating chamber assembly which does not have an electrical insulation layer, such as is shown in FIG. 2, this step will not be necessary.

A resistive heating layer will then be provided on an outer surface of the heating chamber in step 403, either directly on an outer surface of the heating chamber or on an intermediate layer such as an electrical insulation layer.

It will be appreciated that there may be further steps of the method 400 which are not shown. For example, there may be one or more further steps of providing one or more resistive heating layers, which may be prior to step 402, between steps 402 and 403, or after step 403.

In one preferable embodiment, the heating chamber provided is step 401 is made from an electrically non-conductive material such as glass, with a first resistive heating layer provided prior to step 402 and a second resistive heating layer provided in step 403. An electrical insulation layer is also provided in step 402 so as to provide a heating chamber assembly in which two resistive heating layers are separated by an electrical insulation layer.

Advantageously, in the embodiments of the invention described above, at least one resistive heating layer will be tape casted and wrapped around an outer surface of the heating chamber. Further resistive heating layers may also be tape casted, but may alternatively be thermally sprayed on outer surface of the heating chamber, either directly on an outer surface of the heating chamber or on an intermediate layer.

1. A heating chamber assembly for an aerosol generation device, the heating chamber assembly comprising:
a heating chamber configured to receive an aerosol generation substrate; and
a tape casted resistive heating layer on an outer surface of the heating chamber, the tape casted resistive heating layer being configured to deliver heat to the heating chamber.

2. The heating chamber assembly according to claim 1, wherein the tape casted resistive heating layer comprises one or more semiconductors.

3. The heating chamber assembly according to claim 2, wherein the one or more semiconductors comprise one or more ceramic semiconductors.

4. The heating chamber assembly according claim 1, further comprising a thermally sprayed resistive heating layer on an outer surface of the heating chamber, the thermally sprayed resistive heating layer being configured to deliver heat to the heating chamber.

5. The heating chamber assembly according claim 1, wherein the tape casted resistive heating layer comprises one or more electrical insulators.

6. The heating chamber assembly according to claim 1, further comprising an electrical insulation layer between the tape casted resistive heating layer and the heating chamber.

7. The heating chamber assembly according to claim 6, wherein the electrical insulation layer comprises a functionalized silica coating.

8. The heating chamber assembly according to claim 1, wherein the heating chamber is formed from glass.

9. A method of manufacturing a heating chamber assembly for an aerosol generation device, the method comprising:
providing a heating chamber configured to receive an aerosol generation substrate;
tape casting a resistive heating layer, the resistive heating layer being configured to deliver heat to the heating chamber; and
wrapping the taped casted resistive heating layer around an outer surface of the heating chamber.

10. The method according to claim 9, further comprising thermally spraying a resistive heating layer on an outer surface of the heating chamber.

11. The method according to claim 10, wherein thermally spraying the resistive heating layer comprises atmospheric plasma spraying and/or high velocity oxygen fuel spraying.

12. The method according to claim 9, further comprising providing an electrical insulation layer between the resistive heating layer and the heating chamber.

13. The method according to claim 12, wherein providing the electrical insulation layer between the resistive heating layer and the heating chamber comprises applying the electrical insulation layer by chemical vapour deposition.

14. The heating chamber assembly according to claim 3, wherein the one or more ceramic semiconductors include sintered silicon carbide, liquid phase sintered silicon carbide, or silicon infiltrated silicon carbide.

15. The heating chamber assembly according to claim 7, wherein the functionalized silica coating is an organosilica coating.
